(19) United States
(12) Patent Application Publication
(10) Pub. No.: US 2025/0232949 A1
(43) Pub. Date: Jul. 17, 2025

(54) Shield for an Ion Implanter

(71) Applicant: Applied Materials, Inc., Santa Clara, CA (US)

(72) Inventors: Tseh-Jen Hsieh, Rowley, MA (US); Gregory Edward Stratoti, Sandown, NH (US); Santosh Dhulapati, Wakefield, MA (US); Bon-Woong Koo, Andover, MA (US)

(21) Appl. No.: 18/946,776

(22) Filed: Nov. 13, 2024

Related U.S. Application Data
(60) Provisional application No. 63/621,830, filed on Jan. 17, 2024.

(51) Int. Cl. H01J 37/30; H01J 37/20; H01J 37/317

(52) U.S. Cl. CPC H01J 37/3007; H01J 37/20; H01J 37/3171; H01J 2237/026; H01J 2237/20207

(57) ABSTRACT

A shield for use with a rotatable platen is disclosed. The shield includes an exposed portion and a frame to attach the shield to the platen. The exposed portion of the shield has an arc shaped back surface that faces the platen and an opposite exposed surface that faces toward the ion beam. The exposed surface is designed such that the ion beam strikes the exposed surface at angles that are roughly 90°, as sputtering may be reduced at these angles. The exposed surface may have various shapes, including flat, rounded or sloped. Additionally, the exposed surface may include a plurality of exposed segments, separated by connecting segments that are not exposed to the ion beam. The shield may be graphite, silicon or silicon carbide.

This application claims priority of U.S. Provisional Patent Application Ser. No. 63/621, 830, filed Jan. 17, 2024, the disclosure of which is incorporated herein by reference in its entirety.

### FIELD

This disclosure describes embodiments of a shield for use in an ion implanter to protect the platen.

### BACKGROUND

Semiconductor devices are fabricated using a plurality of processes, some of which implant ions into the workpiece. Certain implanters have the ability to monitor the ion beam that is being directed toward the workpiece. The incoming ion beam typically is very narrow in the height direction, but has a width that is greater than the diameter of the workpiece. This width may be achieved using a ribbon ion beam, or by the scanning of a spot ion beam.

The ion beam typically impacts the workpiece at an angle that is normal to the direction of the ion beam. However, in certain embodiments, it may be useful to perform the implant at an angle that is not normal to the ion beam. This may be referred to as an angled implant.

When the workpiece is tilted, it is possible that the ion beam may strike the platen. Therefore, in certain situations, a shield may be disposed around the platen to protect the platen from this ion beam strike. Thus, the purpose of the shield is to be impacted by the ion beam so that the platen is not damaged by the ion beam. However, it is possible that there may be situations where the ion beam causes the shield to sputter, creating undesirable particles.

Therefore, it would be beneficial if there were a shield that protected the platen, but generated fewer particles when impacted by the ion beam.

### SUMMARY

A shield for use with a rotatable platen is disclosed. The shield includes an exposed portion and a frame to attach the shield to the platen. The exposed portion of the shield has an arc shaped back surface that faces the platen and an opposite exposed surface that faces toward the ion beam. The exposed surface is designed such that the ion beam strikes the exposed surface at angles that are roughly 90°, as sputtering may be reduced at these angles. The exposed surface may have various shapes, including flat, rounded or sloped. Additionally, the exposed surface may include a plurality of exposed segments, separated by connecting segments that are not exposed to the ion beam. The shield may be graphite, silicon, silicon carbide or another material.

According to one embodiment, an ion implanter is disclosed. The ion implanter comprises an ion source to generate ions; a platen to support a workpiece that is treated with an ion beam created from the ions, wherein, when the ion beam reaches the workpiece, the ion beam has a longer dimension in an X direction, a smaller dimension in a Y direction, where the Y direction is perpendicular to the X direction, and a direction of travel in a Z direction, wherein the platen is positioned within a process chamber of the ion implanter and comprises a base and an electrostatic chuck; and a shield to protect the electrostatic chuck from the ion beam; wherein the shield comprises a surface that is exposed to the ion beam referred to as an exposed surface, and wherein the ion beam strikes the exposed surface at an angle that deviates from normal by 20° or less when measured in an X-Z plane. In some embodiments, the electrostatic chuck is maintained at an X-tilt angle of at least 60°. In some embodiments, the ion beam strikes the exposed surface at an angle that deviates from normal by 10° or less when measured in the X-Z plane. In some embodiments, the ion beam strikes the exposed surface at a normal angle when measured in the X-Z plane. In some embodiments, the ion beam strikes the exposed surface at an angle that deviates from normal by 20° or less when measured in a Y-Z plane. In some embodiments, the ion beam strikes the exposed surface at a normal angle when measured in a Y-Z plane. In some embodiments, the electrostatic chuck is maintained at an X-tilt angle of θ° relative to vertical, and an angle between the exposed surface and a top surface of the electrostatic chuck in a Y-Z plane is 180-θ° or less. In some embodiments, an angle between the exposed surface and a top surface of the electrostatic chuck in a Y-Z plane is acute. In some embodiments, the shield is made from graphite.

According to another embodiment, a shield for use with a platen is disclosed. The shield comprises an exposed portion; and a frame connecting the exposed portion to the platen; wherein the exposed portion comprises a back surface, configured to be adjacent to the platen and having an arc shape, and an exposed surface, opposite the back surface, that is adapted to be exposed to an ion beam, wherein the exposed portion has a first dimension, referred to as a width, that is at least as wide as the platen and wherein the exposed surface is substantially straight along the first dimension. In some embodiments, the exposed surface is configured such that it does not bend, curve or slope more than 10° along the first dimension. In some embodiments, the exposed surface is flat along the first dimension. In some embodiments, the exposed portion comprises a top surface, and the top surface and the exposed surface form an acute angle. In some embodiments, the exposed portion is graphite. In some embodiments, the exposed portion comprises a top surface, and the top surface and the exposed surface form an obtuse angle such that the exposed surface is substantially perpendicular to the ion beam in two directions.

According to another embodiment, a shield for use with a platen is disclosed. The shield comprises an exposed portion; and a frame connecting the exposed portion to the platen; wherein the exposed portion comprises a back surface, configured to be adjacent to the platen and having an arc shape, and an exposed surface, opposite the back surface, that is adapted to be exposed to an ion beam, wherein the exposed portion has a first dimension, referred to as a width, that is at least as wide as the platen and wherein the exposed surface comprises a plurality of exposed segments that are configured to be substantially parallel to one another in the first dimension and a plurality of connecting segments disposed between adjacent exposed segments, wherein the connecting segments form an angle of 90° or less with the adjacent exposed segments. In certain embodiments, the plurality of exposed segments are parallel to one another. In certain embodiments, the connecting segments form an angle of less than 90° with the adjacent exposed segments. In some embodiments, the exposed portion is graphite. In some embodiments, the exposed portion comprises a top surface, and the top surface and the exposed surface form an obtuse angle such that the exposed surface is substantially perpendicular to the ion beam in two directions.

### BRIEF DESCRIPTION OF THE DRAWINGS

For a better understanding of the present disclosure, reference is made to the accompanying drawings, in which like elements are referenced with like numerals, and in which:

FIG. 1 is a block diagram of an ion implanter that uses the shield according to one embodiment;

FIG. 2 is a block diagram of a process chamber with a platen and shield;

FIG. 3 shows rotation and tilt of a workpiece on the platen;

FIG. 4 shows the process chamber with the electrostatic chuck at a large X-tilt angle;

FIG. 5 shows a top view of a shield according to one embodiment;

FIGS. 6A-6C show a top view of the shield according to several different embodiments;

FIGS. 7A-7C show a side view of the shield according to several different embodiments; and

FIG. 8 shows a side view of the shield according to another embodiment.

### DETAILED DESCRIPTION

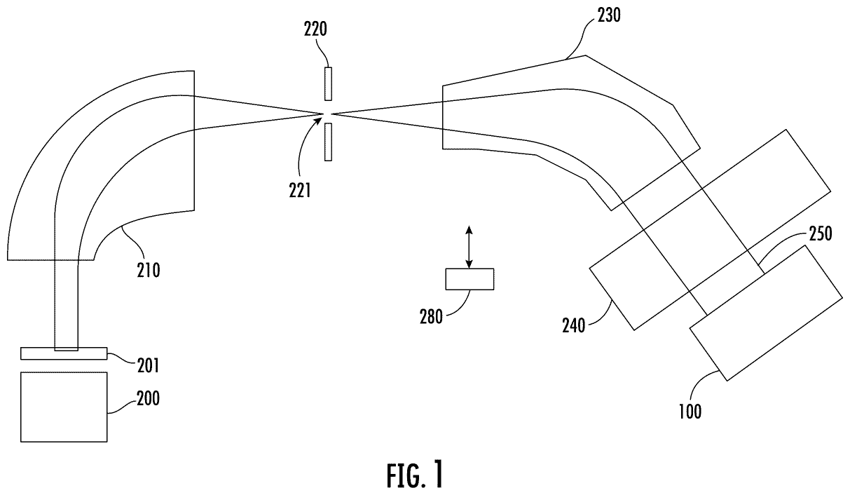

FIG. 1 shows an ion implanter that includes a process chamber 100 that contains a platen and a shield. An ion source 200 is used to generate ions. The ion source 200 may be an indirectly heated cathode (IHC) ion source. Alternatively, the ion source 200 may be a capacitively coupled plasma source, an inductively coupled plasma source, a Bernas source or another source. Thus, the type of ion source is not limited by this disclosure. Disposed outside and proximate the extraction aperture of the ion source 200 is the extraction optics 201, which may comprise one or more electrodes.

Located downstream from the extraction optics 201 is a mass analyzer 210. The mass analyzer 210 uses magnetic fields to guide the path of the extracted ion beam. The magnetic fields affect the flight path of ions according to their mass and charge. A mass resolving device 220 that has a resolving aperture 221 is disposed at the output, or distal end, of the mass analyzer 210. By proper selection of the magnetic fields, only those ions in the extracted ion beam that have a selected mass and charge will be directed through the resolving aperture 221. Other ions will strike the mass resolving device 220 or a wall of the mass analyzer 210 and will not travel any further in the system.

A collimator 230 may be disposed downstream from the mass resolving device 220. The collimator 230 accepts the ions from the ion beam that pass through the resolving aperture 221 and creates an ion beam 250 formed of a plurality of parallel or nearly parallel beamlets. The output, or distal end, of the mass analyzer 210 and the input, or proximal end, of the collimator 230 may be a fixed distance apart. The mass resolving device 220 is disposed in the space between these two components.

Located downstream from the collimator 230 may be an acceleration/deceleration stage 240. The acceleration/deceleration stage 240 is a beam-line lens component configured to independently control deflection, deceleration, and focus of the ion beam 250. For example, the acceleration/deceleration stage 240 may be an electrostatic filter (EF). The ion beam 250 that exits the acceleration/deceleration stage 240 enters the process chamber 100.

A controller 280 may be in communication with one or more of the power supplies such that the voltage or current supplied by these power supplies may be monitored and/or modified. The controller 280 may include a processing unit, such as a microcontroller, a personal computer, a special purpose controller, or another suitable processing unit. The controller 280 may also include a non-transitory storage element, such as a semiconductor memory, a magnetic memory, or another suitable memory. This non-transitory storage element may contain instructions and other data that allows the controller 280 to perform the functions described herein.

In certain embodiments, the ion source 200 may generate a ribbon ion beam that travels through these components. Thus, while FIG. 1 shows a ribbon ion beam system, it is understood that the ion implantation system may utilize a scanned beam. Such an ion implanter includes an ion source that creates ions in the form or a spot ion beam. This type of ion implanter also includes a mass analyzer and a mass resolving device, as described above. In addition, a scanner, which may be electrostatic or another type is used to create a scanned ion beam. Specifically, the spot beam may enter an electrostatic scanner, which is used to scan the spot beam in the width direction so as to form the scanned ion beam, which is in the form of an ion beam having a width much larger than its height. The scanned ion beam may then pass through an angle corrector. The angle corrector is designed to deflect ions in the scanned ion beam to produce an ion beam having parallel ion trajectories, thus focusing the scanned ion beam. Specifically, the angle corrector is used to alter the diverging ion trajectory paths into substantially parallel paths of the ion beam 250. In some embodiments, the angle corrector may comprise magnetic pole pieces which are spaced apart to define a gap and a magnet coil which is coupled to a power supply. The scanned ion beam passes through the gap between the magnetic pole pieces and is deflected in accordance with the magnetic field in the gap. In other embodiments, the angle corrector may be an electrostatic lens, sometimes referred to as a parallelizing lens.

In both configurations, when the ion beam 250 reaches the workpiece, the ion beam has a larger dimension in the X direction and a smaller dimension in the Y direction. The X direction may be referred to as the width of the ion beam while the Y direction may be referred to as the height of the ion beam. The X direction and Y direction are perpendicular to one another. Further, the ion beam 250 travels in the Z direction.

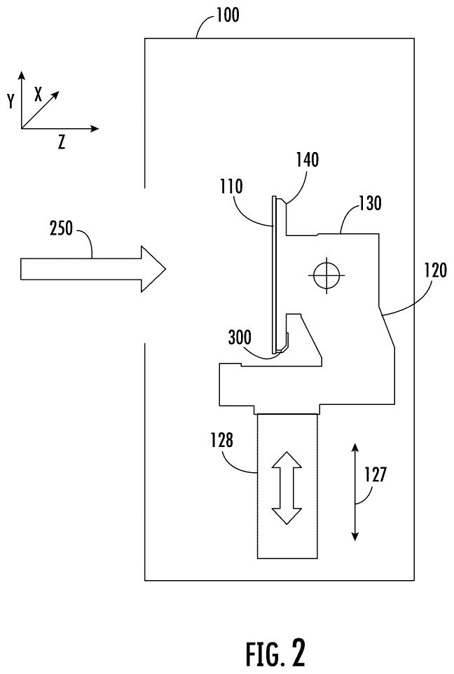

FIG. 2 shows the process chamber 100 of FIG. 1 in more detail. The process chamber 100 includes a platen 120, on which a workpiece 110 may be disposed. When in the operational position, the ion beam 250 impacts the workpiece 110. The platen 120 may include an electrostatic chuck 140 that is used to clamp and hold the workpiece 110 while the ion beam 250 is directed into the process chamber 100. In some embodiments, the platen 120 may be elevated and lowered in a Y direction 127 through the movement of shaft 128.

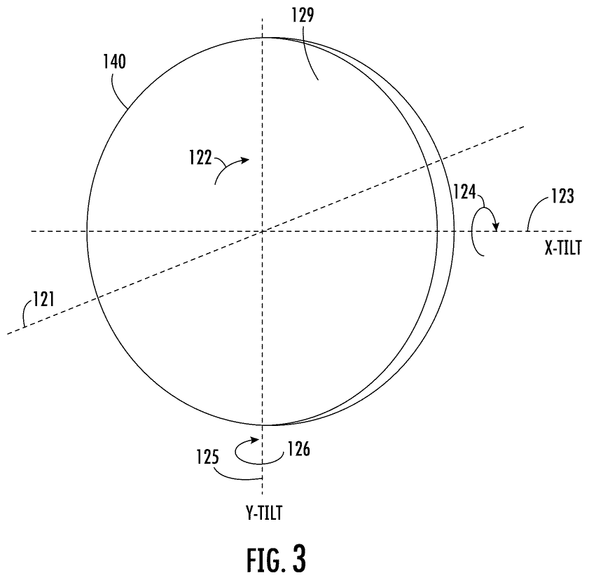

Additionally, the platen 120 may rotate about different axis. FIG. 3 shows the platen 120 and its various directions of rotation. FIG. 3 shows a perspective view of the platen 120 that is capable of rotation, referred to as a roplat. As seen in FIG. 2, the roplat includes a base 130 and an electrostatic chuck 140. The electrostatic chuck 140 includes one or more electrodes that enable the electrostatic chuck to generate an electrostatic force that clamps the workpiece 110 to the clamping surface 129. The electrostatic chuck 140 is rotatably coupled to the base 130. The platen 120 may have three axes. There may be a twist axis 121, which is perpendicular to the clamping surface 129 of the electrostatic chuck k 140 and passes through the center of the electrostatic chuck 140. Rotation about this twist axis 121 is referred to as a twist angle 122. Note that the electrostatic chuck 140 is rotatable about the twist axis 121, while the base 130 remains fixed. There is an X axis 123 that passes through the platen, is parallel to the clamping surface 129 of the platen 120 and is perpendicular to the twist axis 121. The X axis 123 is parallel to the wide dimension of the ion beam 250. Tilting about the X axis 123 is referred to as an X-tilt angle 124 and is achieved by rotation of the electrostatic chuck 140 on the base 130. X-tilt angles are measured with respect to the vertical direction. In other words, when the clamping surface 129 is vertical, as shown in FIG. 2, the X-tilt angle is defined as 0°. An X-tilt angle of 90° is defined as being in the horizontal position. There is also a Y axis 125 that also passes through the platen 120, is parallel to the clamping surface 129 of the platen 120 and is perpendicular to the twist axis 121 and the X axis 123. The Y axis 125 is parallel to the narrow dimension of the ion beam 250. Tilting about the Y axis 125 is referred to as a Y-tilt angle 126 and may be achieved by movement of the base 130. For example, the Y-tilt angle 126 may be achieved by rotation of shaft 128.

In certain embodiments, the electrostatic chuck 140 may be rotated 90° about the X axis 123, so that the clamping surface 129 of the electrostatic chuck 140 is horizontal, allowing a workpiece 110 to be placed on the platen 120. This may be referred to as the loading position. The electrostatic chuck 140 is then rotated about the X axis 123 into the operational, or implant position, which is shown in FIG. 2.

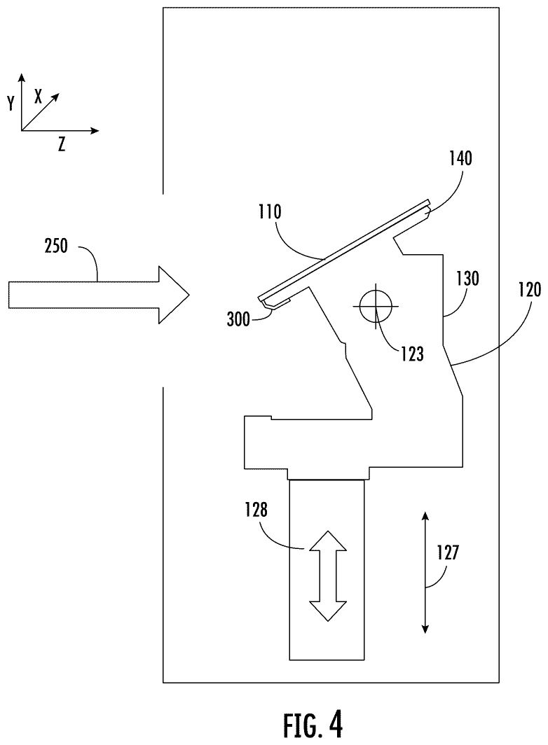

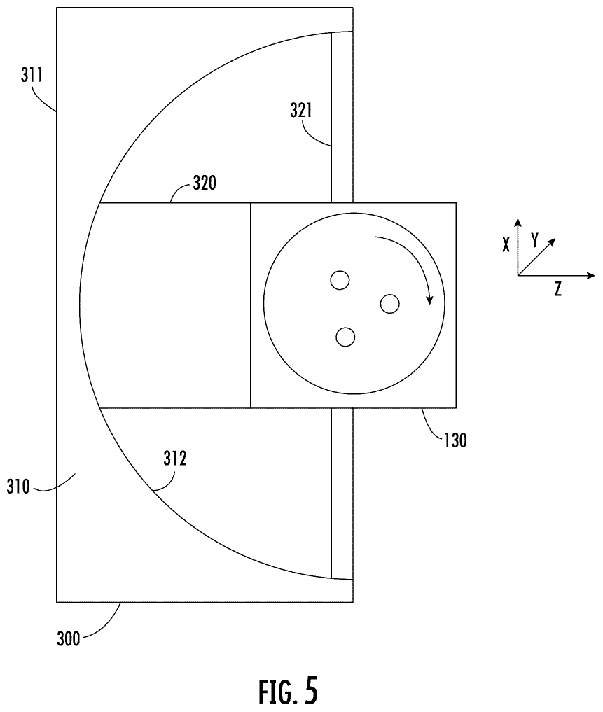

Note that, as shown in FIG. 4, when the electrostatic chuck 140 is tilted about the X axis 123, the bottom portion of the electrostatic chuck 140 may be exposed to the incoming ion beam 250. Thus, to protect the electrostatic chuck 140, a shield 300 may be added. FIG. 5 shows a top view of a shield 300 when the platen 120 is in the loading position. The shield 300 includes an exposed portion 310, which is positioned along the lower portion of the electrostatic chuck 140. The lower portion is defined as the portion of the electrostatic chuck 140 that faces the ion beam 250 when the electrostatic chuck 140 is in the loading position. The exposed portion 310 has a first dimension along the X direction (also referred to as the width) that is typically wider than the electrostatic chuck 140 and a second dimension, perpendicular to the first direction, which is smaller than the first dimension (also referred to as the length). The second dimension is parallel to the Z direction when the platen is in the loading position. The exposed portion 310 also has a thickness, which is perpendicular to the first dimension and the second dimension and is parallel to the Y direction when the platen is in the loading position. The exposed portion 310 also has a top surface that may be parallel to the top surface of the electrostatic chuck 140.

The exposed portion 310 has an exposed surface 311, which faces the ion beam 250 and extends along the first dimension. The exposed portion 310 also has a back surface 312, which faces the electrostatic chuck 140. In some embodiments, the back surface 312 is arc shaped with a diameter that is slightly larger than the diameter of the electrostatic chuck 140. The shield 300 also includes a frame 320, which is used to attach the exposed portion 310 to the base 130. The frame 320 may have one or more brackets 321 to attach the exposed portion 310 to the base 130.

The exposed portion 310 of the shield 300 may be constructed from graphite. It has been found that sputtering of a graphite surface is minimized when the ion beam strikes the graphite at an angle that is normal to the surface of the graphite. Further, sputtering is increased as the angle formed between the ion beam and the graphite surface deviates from normal. Specifically, the amount of sputtering remains low up to angles that are about 20° from normal, and increases more quickly as the angle deviates more than this.

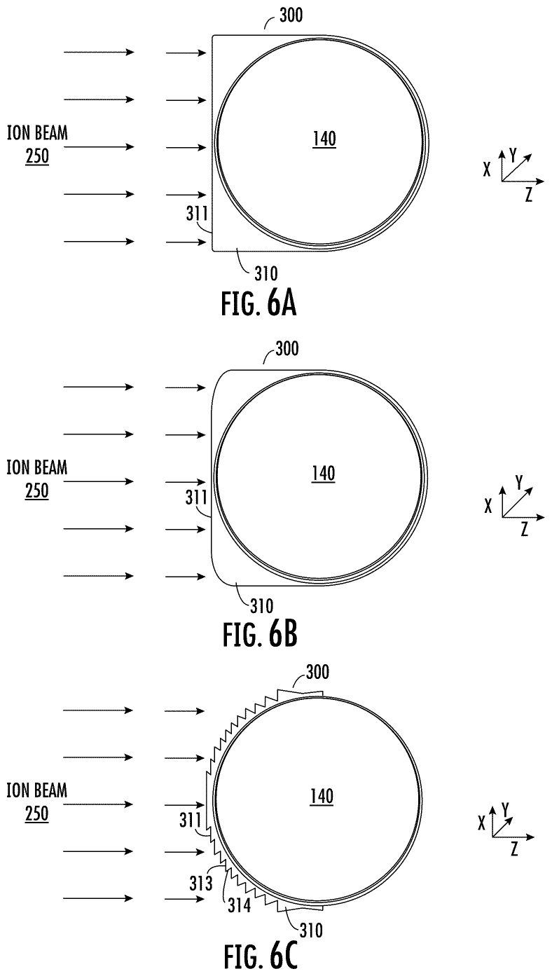

Thus, in one embodiment, the exposed surface 311 of the shield 300 is flat along its width (i.e. the X direction), and perpendicular to the incoming ion beam 250 in the X-Z plane, as shown in FIG. 6A. Note that, in this embodiment, the ion beam 250 is perpendicular to the exposed surface 311 in the X-Z plane over the entire width where the ion beam 250 strikes the exposed surface 311. In other words, when viewed from above, the ion beam is perpendicular to the exposed surface 311.

However, as noted above, the amount of sputtering remains low as long as the angle of incidence does not deviate from normal by more than 20°. Thus, in another embodiment, shown in FIG. 6B, the exposed surface 311 is not flat in the X direction, but has a curve or slope. However, the radius of the curve or slope is selected such that the ion beam 250 does not strike the exposed surface 311 at an angle that is less than 70° or more than 110° (when measured in the X-Z plane). In another embodiment, the angle of incidence does not deviate from normal by more than 10°. Thus, the radius of the curve or slope is selected such that the ion beam 250 does not strike the exposed surface 311 at an angle that is less than 80° or more than 100° (when measured in the X-Z plane). In other words, the exposed surface 311 is substantially straight. In this disclosure, the term “substantially straight” denotes that the exposed surface 311 is configured so as not to bend, curve or slope more than 20° in either direction along the width that is exposed to the ion beam 250. Further, in certain embodiments, the exposed surface 311 is configured so as not to bend, curve or slope more than 10° in either the width or thickness directions.

Note that FIGS. 6A-6B include a large exposed portion. In other embodiments, the size of the exposed portion 310 is reduced. FIG. 6C shows one such embodiment. In this embodiment, the exposed surface 311 comprises a plurality of exposed segments 313, that are each normal to the incoming ion beam 250 in the X-Z plane. Between adjacent exposed segments 313 are connecting segments 314. The connecting segments 314 may form angles that are perpendicular to adjacent exposed segments 313. In other embodiments, the connecting segments 314 may form acute angles with both adjacent exposed segments 313. In this way, the connecting segments 314 are not exposed to the ion beam 250. In another embodiment, the exposed segments 313 form an angle that deviates by 20° or less from normal relative to the ion beam 250 in the X-Z plane. In other words, the exposed segments 313 may be substantially parallel to one another. The term “substantially parallel” indicates that the direction of each exposed segment 313 is within 20° of the direction of any other exposed segment 313 and within 20° of normal to the ion beam 250. In certain embodiments, like that shown in FIG. 6C, the exposed segments 313 are parallel to one another and normal to the ion beam 250 in the X-Z plane.

While FIGS. 6A-6C show several different embodiments, the disclosure is not limited to those illustrated herein. Rather, any shield 300 in which the exposed surface 311 which is exposed to the ion beam 250 creates an angle of between 70° and 110° with the ion beam 250 in the X-Z plane may be utilized.

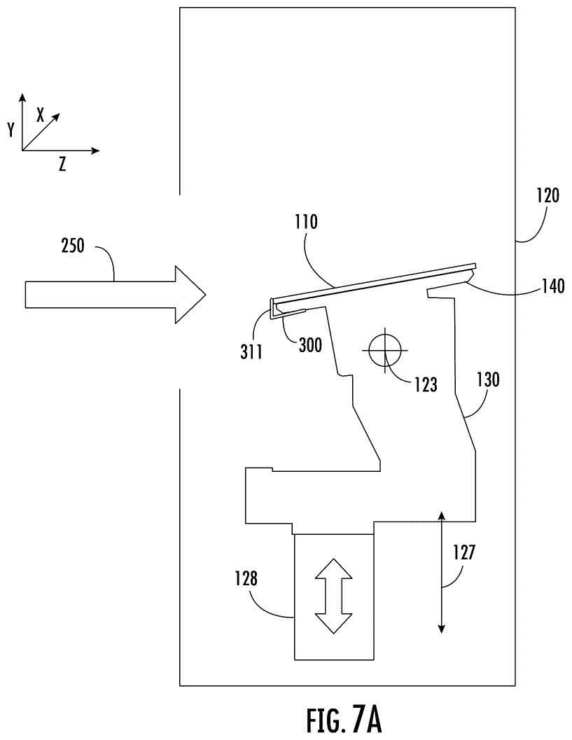

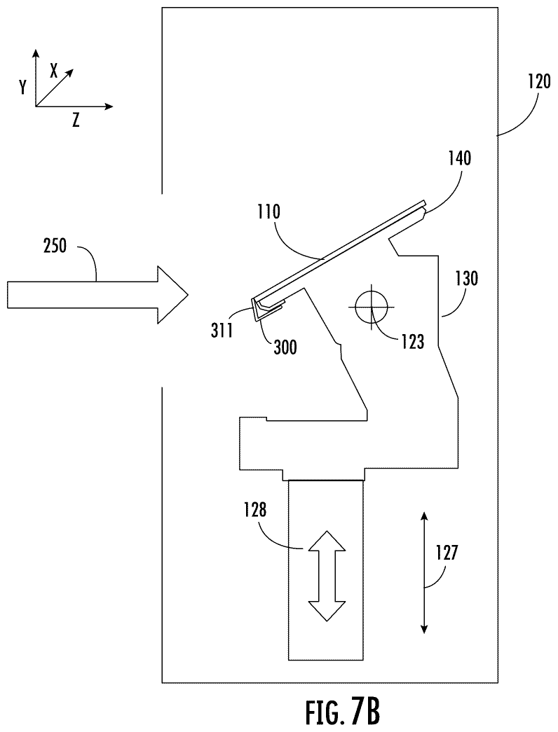

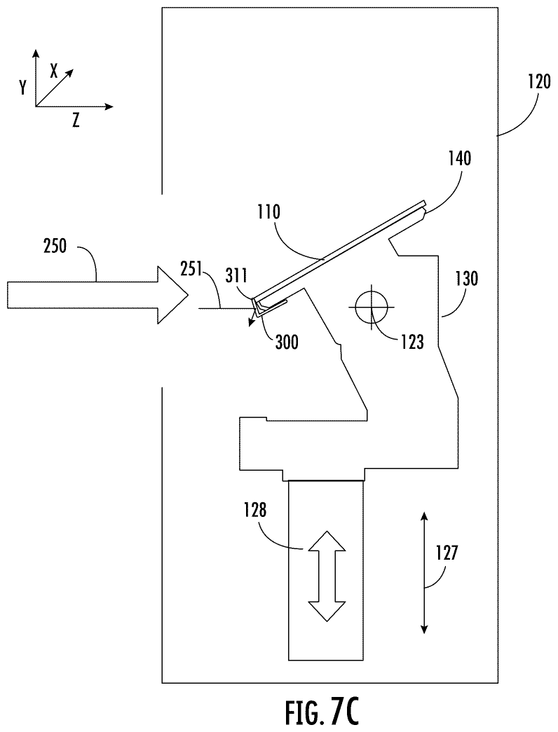

However, the exposed surface 311 also has a thickness, which is the Y direction when the platen 120 is in the loading position. Thus, in some embodiments, as shown in FIGS. 7A-7B, the shield 300 is configured such that the exposed surface 311 is perpendicular to the ion beam 250 in the Y-Z plane. Note that the electrostatic chuck 140 may be disposed at different X tilt angles. FIG. 7A shows the electrostatic chuck 140 at a X-tilt angle of 80°, and a shield 300 with an exposed surface 311 that is perpendicular to the incoming ion beam 250 in in Y-Z plane.

FIG. 7B shows the electrostatic chuck 140 at a X-tilt angle of 60°, and a shield 300 with an exposed surface 311 that is perpendicular to the incoming ion beam 250 in the Y-Z plane. Note that, in order to have the exposed surface 311 perpendicular to the ion beam 250 in the Y-Z plane, different shields are used for each X tilt angle.

Thus, in one embodiment, a set of shields is disclosed wherein each shield has an exposed surface 311 configured such that the ion beam 250 does not strike the exposed surface 311 at an angle that is less than 70° or more than 110° (when measured in the X-Z plane). Further, each shield is configured for a specific X-tilt angle such that the exposed surface 311 is perpendicular to the ion beam 250 in the Y-Z plane.

In order for the exposed surface 311 to be perpendicular to the ion beam 250 in the Y-Z plane, if the X-tilt angle is given by θ, the angle formed by the top surface of the electrostatic chuck 140 and the exposed surface of the shield 300 (in the Y-Z plane) is given by 180-θ. Since θ is always less than 90°, the angle formed between the top surface and the exposed surface of the shield 300 may be obtuse.

Note that the angle at which the ion beam 250 strikes the exposed surface 311 may deviate from normal in the Y-Z plane. As described above, the amount of sputtering is low if the angle deviates from normal by less than 20°. Thus, in some embodiments, the exposed surface 311 is substantially perpendicular to the ion beam in two directions. The term “substantially perpendicular” indicates that the edge of the exposed surface 311 that is contacted by the ion beam is within 20° of normal to the ion beam 250 in the Y-Z and X-Z planes.

Thus, a shield 300 that includes an exposed surface 311 that forms a 70° angle with the top surface of the electrostatic chuck 140 in the Y-Z plane may be used for implants that have tilt angles between 50° and 90°. Thus, a range of tilt angles may be served by a single shield.

Furthermore, in some embodiments, it may be desirable for the angle to deviate from normal such that the ion beam 250 is deflected from the exposed surface 311 in the downward direction. FIG. 7C shows an embodiment where the shield 300 of FIG. 7A is disposed on an electrostatic chuck 140 at a tilt angle of 60°. Beamlet 251 strikes the shield 300 and is deflected downward, away from the workpiece 110. Thus, in these embodiments, the angle formed between the top surface of the electrostatic chuck 140 and the exposed surface of the shield 300 (in the Y-Z plane) is less than 180-θ, where θ is the X-tilt angle.

In this scenario, the shield designed for an X-tilt angle of θ may be used with an electrostatic chuck 140 at an X-tilt angle of less than θ. However, in certain embodiments, the converse may not be true, such that the shield designed for an X-tilt angle of θ may not be used with an electrostatic chuck 140 at a X-tilt angle greater than θ.

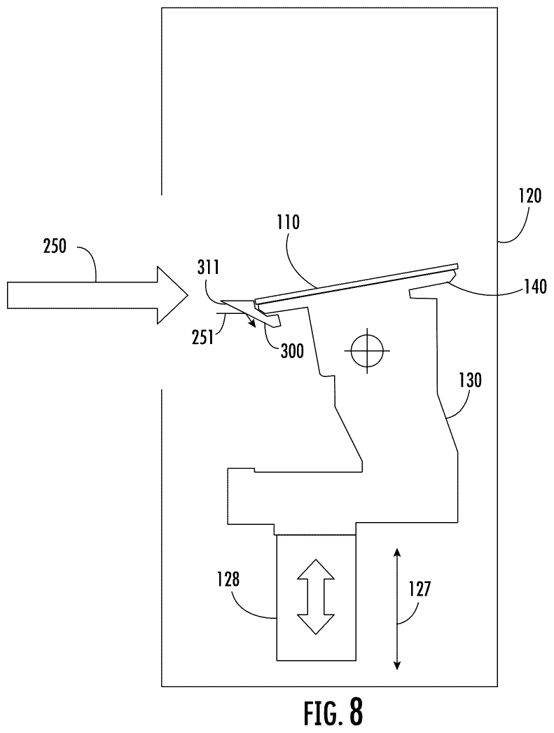

In certain embodiments, the angle between the top surface of the electrostatic chuck 140 and the exposed surface 311 in the Y-Z plane may be an acute angle, as shown in FIG. 8. In this embodiment, beamlets 251 from the ion beam 250 that strike the exposed surface 311 will be deflected downward toward the base 130.

While the exposed portion 310 is described as being graphite, it is understood that other materials, such as single crystal silicon, silicon carbide, nickel, yttrium, zirconium, and doped diamond-like carbon (DLC) may also be used.

The present system has many advantages. Traditional shields have an exposed surface that is arc shaped. Thus, the ion beam strikes the exposed surface at different angles along the X direction. In the middle of the ion beam, the ion beam may be perpendicular to the exposed surface, however, nearer to the edges of the ion beam, the angle of contact may be much smaller. As described above, the amount of sputtering of the shield may be related to the angle at which the ion beam strikes the exposed surface. By changing the design of the shield so that the exposed surface of the shield that is impacted by the ion beam is substantially perpendicular to the ion beam, the amount of particles generated by the sputtering of the shield may be decreased. Additionally, this design may be accommodated in the space that is presently used by the current shield.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. An ion implanter, comprising;
an ion source to generate ions;
a platen to support a workpiece that is treated with an ion beam created from the ions, wherein, when the ion beam reaches the workpiece, the ion beam has a longer dimension in an X direction, a smaller dimension in a Y direction, where the Y direction is perpendicular to the X direction, and a direction of travel in a Z direction, wherein the platen is positioned within a process chamber of the ion implanter and comprises a base and an electrostatic chuck; and
a shield to protect the electrostatic chuck from the ion beam;
wherein the shield comprises a surface that is exposed to the ion beam referred to as an exposed surface, and wherein the ion beam strikes the exposed surface at an angle that deviates from normal by 20° or less when measured in an X-Z plane.

2. The ion implanter of claim 1, wherein the electrostatic chuck is maintained at an X-tilt angle of at least 60°.

3. The ion implanter of claim 1, wherein the ion beam strikes the exposed surface at an angle that deviates from normal by 10° or less when measured in the X-Z plane.

4. The ion implanter of claim 1, wherein the ion beam strikes the exposed surface at a normal angle when measured in the X-Z plane.

5. The ion implanter of claim 1, wherein the ion beam strikes the exposed surface at an angle that deviates from normal by 20° or less when measured in a Y-Z plane.

6. The ion implanter of claim 1, wherein the ion beam strikes the exposed surface at a normal angle when measured in a Y-Z plane.

7. The ion implanter of claim 1, wherein the electrostatic chuck is maintained at an X-tilt angle of θ° relative to vertical, and an angle between the exposed surface and a top surface of the electrostatic chuck in a Y-Z plane is 180-θ° or less.

8. The ion implanter of claim 1, wherein an angle between the exposed surface and a top surface of the electrostatic chuck in a Y-Z plane is acute.

9. The ion implanter of claim 1, wherein the shield is made from graphite.

10. A shield for use with a platen, comprising:
an exposed portion; and
a frame connecting the exposed portion to the platen;
wherein the exposed portion comprises a back surface, configured to be adjacent to the platen and having an arc shape, and an exposed surface, opposite the back surface, that is adapted to be exposed to an ion beam, wherein the exposed portion has a first dimension, referred to as a width, that is at least as wide as the platen and wherein the exposed surface is substantially straight along the first dimension.

11. The shield of claim 10, wherein the exposed surface is configured such that it does not bend, curve or slope more than 10° along the first dimension.

12. The shield of claim 10, wherein the exposed surface is flat along the first dimension.

13. The shield of claim 10, wherein the exposed portion comprises a top surface, and the top surface and the exposed surface form an acute angle.

14. The shield of claim 10, wherein the exposed portion is graphite.

15. The shield of claim 10, wherein the exposed portion comprises a top surface, and the top surface and the exposed surface form an obtuse angle such that the exposed surface is substantially perpendicular to the ion beam in two directions.

16. A shield for use with a platen, comprising:
an exposed portion; and
a frame connecting the exposed portion to the platen;
wherein the exposed portion comprises a back surface, configured to be adjacent to the platen and having an arc shape, and an exposed surface, opposite the back surface, that is adapted to be exposed to an ion beam, wherein the exposed portion has a first dimension, referred to as a width, that is at least as wide as the platen and wherein the exposed surface comprises a plurality of exposed segments that are configured to be substantially parallel to one another in the first dimension and a plurality of connecting segments disposed between adjacent exposed segments, wherein the plurality of connecting segments form an angle of 90° or less with the adjacent exposed segments.

17. The shield of claim 16, wherein the plurality of exposed segments are parallel to one another.

18. The shield of claim 16, wherein the plurality of connecting segments form an angle of less than 90° with the adjacent exposed segments.

19. The shield of claim 16, wherein the exposed portion is graphite.

20. The shield of claim 16, wherein the exposed portion comprises a top surface, and the top surface and the exposed surface form an obtuse angle such that the exposed surface is substantially perpendicular to the ion beam in two directions.
